(19) United States
(12) Patent Application Publication
(10) Pub. No.: US 2026/0251732 A1
(43) Pub. Date: Aug. 27, 2026

(54) Self-Calibrating Magnetometer

(71) Applicant: The Regents of The University of Michigan, Ann Arbor, MI (US)

(72) Inventors: Cole DORMAN, Ann Arbor, MI (US); Julio VATA, Ann Arbor, MI (US); Lauro V. OJEDA, Ann Arbor, MI (US); Mark B. MOLDWIN, Ann Arbor, MI (US)

(73) Assignee: The Regents of The University of Michigan, Ann Arbor, MI (US)

(21) Appl. No.: 19/549,176

(22) Filed: Feb. 25, 2026

Related U.S. Application Data
(60) Provisional application No. 63/763,426, filed on Feb. 26, 2025.

(51) Int. Cl. G01R 33/00; G01R 33/02

(52) U.S. Cl. CPC G01R 33/0035; G01R 33/0206

(57) ABSTRACT

A self-calibrating magnetometer comprising a magnetometer, a set of Helmholtz coils, a current source, and a controller is presented. The magnetometer has three sense coils arranged to detect magnetic fields along three axes. The Helmholtz coils are arranged adjacent to the magnetometer and configured to generate magnetic fields for calibration. The current source energizes the set of Helmholtz coils with a signal that varies over time and the controller determines a calibration for the magnetometer by comparing the magnetic fields detected by the magnetometer to an expected magnetic field.

### CROSS-REFERENCE TO RELATED APPLICATIONS

This application claims the benefit and priority of U.S. Provisional Application No. 63/763,426 filed on Feb. 16, 2025. The entire disclosure of the above application is incorporated herein by reference.

### GOVERNMENT CLAUSE

This invention was made with government support under 80NSSC24K0734, and 80NSSC24K0641 awarded by the National Aeronautics and Space Administration. The government has certain rights in the invention.

### FIELD

The present disclosure relates to a self-calibrating magnetometer in spaceborne applications.

### BACKGROUND

Magnetic fields are a pervasive feature of Earth's planetary system. In Earth's orbit, the magnetic field is a combination of internal geodynamic-generated field and external currents generated by processes in space, particularly during substorms and geomagnetic storms. The dynamic nature of planetary magnetospheres makes it difficult to fully understand their structure without a magnetometer that is stable and accurate enough to distinguish between the various wave populations within the magnetosphere and detect the magnetic signatures of plasma flows and currents driven by global and local circulation patterns. Furthermore, magnetometers are used for satellite attitude determination and navigation. Thus, magnetometers are often essential parts of satellite sensor packages.

Earth's magnetosphere contains a diverse array of magnetic field strengths, waves and features, ranging from 60,000 nT in polar low-Earth orbit to 100 nT at geosynchronous orbit, with magnetic field waves spanning a few mHz to a few Hz on both the dayside and nightside, and dynamic signatures from currents and geomagnetic activity. These magnetic fields are shaped by key current systems such as field-aligned currents, electrojets, and boundary currents, which play a critical role in transferring energy throughout the magnetosphere.

As the scientific community's interest in using small satellites for magnetospheric and heliosphere studies grows, there is an increasing demand for space instruments that are more cost-effective and easier to manufacture. This has led to the exploration of various options, including the use of commercial off-the-shelf (COTS) components or even complete instruments. In addition, there is a scientific need for small satellite constellation missions for simultaneous multipoint sampling to better understand the dynamics of Earth's. For these science goals and baseline navigation, spacecraft would best be equipped with high-quality, low-cost, COTS magnetic sensors.

Yet using magnetometers for the study of the dynamics of Earth's magnetosphere is not straightforward because most sensors are not absolute field instruments and their errors drift with time. Relatively inexpensive and lightweight chip-based magnetometers are manufacturable while being low-mass, low-volume, and low-power, but also measure the variability of magnetic fields as opposed to the absolute magnetic field without careful pre- and in-flight calibration. They also have significantly less flight heritage in understanding gain and offset changes as a function of time. Thus, various methods have been proposed to address magnetometer errors and calibrate magnetometers.

Sensors with significant heritage, such as fluxgates, are more accurate and stable than chip-based magnetic sensors. However, they still require careful pre-flight and continuous on-orbit calibration to measure the absolute magnetic field. These sensors also come with non-negligible cost, power, and mass requirements. While they are suitable for a wide range of missions, there is growing demand for more cost- and power-efficient options, particularly for spacecraft constellations.

Many in-flight calibration methods for magnetometers also use multi-sensor comparison and maneuver techniques for calibration. However, multi sensor comparisons greatly increase the power and cost budget, and calibration maneuvers rely on geomagnetic field models (which are subject to their own errors) and disrupt the activities of other sensors. For constellation missions that have a budget for only one magnetic sensor per spacecraft, a popular solution to these issues is low-cost magnetic sensors calibrated using single sensor attitude-independent algorithms. Several algorithms have been developed to tackle this problem, each with different approaches. Each of these calibration methods have their own trade-offs and find their place on constellation missions that can afford computational flexibility but strict cost, power, and mass requirements.

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

This section provides a general summary of the disclosure and is not a comprehensive disclosure of its full scope or all of its features.

In one aspect, a self-calibrating magnetometer system is presented. The self-calibrating magnetometer comprises a magnetometer, a set of Helmholtz coils, a current source, a temperature sensor, and a controller. The magnetometer has three internal sense coils arranged to detect magnetic fields along three axes. Each sense coil is configured to detect magnetic fields along one of the three axes and the three axes are orthogonal to each other. The set of Helmholtz coils are arranged adjacent to the magnetometer and configured to generate magnetic fields for calibration. Each Helmholtz coil pair is arranged in parallel with one of the three axes. The current source is electrically coupled to the set of Helmholtz coils, where the current source energizes the set of Helmholt coils with a signal that varies over time. The controller is interfaced with the magnetometer to receive the magnetic fields detected by the three sense coils and determines a calibration for the magnetometer by comparing the magnetic fields detected by the three sense coils to an expected magnetic field.

In another aspect, the current source energizes the set of Helmholtz coils with an alternating current.

In another aspect, the current source is configured to energize each coil in the set of Helmholtz coils with a sinusoid signal having a different frequency from the other two coils in the set of Helmholtz coils. The sinusoid current signal in the Helmholtz coils creates known sinusoid magnetic fields for in-flight calibration of the sensors.

In another aspect, the controller determines a calibration for the magnetometer using an algorithm that constructs an error matrix using the magnetic fields detected by the three sense coils, where, for each of the three sense coils, the error matrix represents the magnitude of the magnetic field sine wave amplitude along each of the three axes; representing the expected magnetic fields with a normalization matrix; calculating a calibration matrix using the error matrix and the normalization matrix; and correcting the magnetic fields detected by the magnetometer using the calibration matrix.

In another aspect, the calibration matrix from the algorithm is calculated by computing the error matrix multiplied by the transposed normalization matrix multiplied by the pseudoinverse of the normalization matrix multiplied by the transposed normalization matrix.

In another aspect, the self-calibrating magnetometer further comprises a current sensor coupled to each Helmholtz coil in the set of Helmholtz coils and configured to measure current applied to the Helmholtz coil.

In another aspect, the controller regulates the current applied to the Helmholtz coils by the current source based on the desired magnetic field

In another aspect, the self-calibrating magnetometer further comprises a temperature sensor arranged proximate to the magnetometer and interfaced with the controller. The controller records deviations in magnetic fields detected from the magnetometer in relation to a measured temperature from the temperature sensor.

In another aspect, the magnetometer, the set of Helmholtz coils, the current source and the controller reside in a housing.

Further areas of applicability will become apparent from the description provided herein. The description and specific examples in this summary are intended for purposes of illustration only and are not intended to limit the scope of the present disclosure.

### BRIEF DESCRIPTION OF THE DRAWINGS

The drawings described herein are for illustrative purposes only of selected embodiments and not all possible implementations, and are not intended to limit the scope of the present disclosure.

FIG. 1 is a block diagram of a self-calibrating magnetometer system.

FIG. 2 is a diagram of a non-orthogonality error sensor model;

FIG. 3 is a graph of an ideal single axis (x-axis) sinusoid magnetic field;

FIG. 4 is a graph of the single axis (x-axis) sinusoid magnetic field as measured by a magnetometer;

FIG. 5 is a schematic of electronics used by the magnetometer;

FIGS. 6A-6C are diagrams showing the arrangement of the magnetometer is relation the Helmholz coils in a top down view in the Y-X plane, a side view in the Z-X plane and a side view in the Z-Y plane, respectively;

FIGS. 7A and 7B are graphs showing a Bio-Savart magnetic field from the single axis (y-axis) of the self-calibrating magnetometer system;

FIG. 8 is an exploded view of a self-calibrating magnetometer system residing in a housing; and

FIG. 9 is a schematic depicting an example embodiment of the self-calibrating magnetometer system.

Corresponding reference numerals indicate corresponding parts throughout the several views of the drawings.

### DETAILED DESCRIPTION

Example embodiments will now be described more fully with reference to the accompanying drawings.

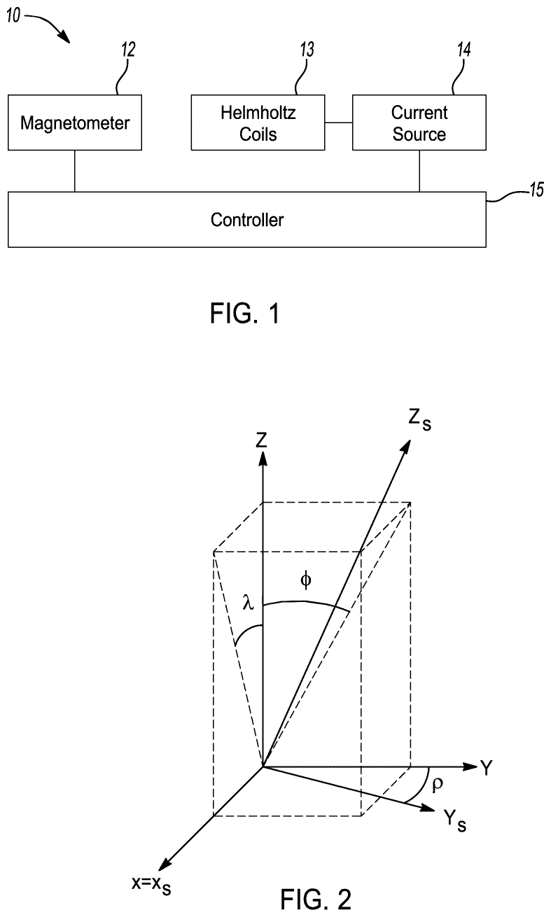

FIG. 1 depicts a self-calibrating magnetometer system 10 for spacecraft constellations that require low cost, low power and computationally simple magnetic field measurements with accuracy and stability. The self-calibrating magnetometer system 10 is comprised of a magnetometer 12, a set of Helmholtz coils, a current source 14 and a controller 15. The use of the coiled Helmholtz inductive magnetometer ensemble leads to this system being referred to herein as CHIME.

In an example embodiment, the magnetometer 12 has three sense coils arranged to detect magnetic fields along three axes. Each sense coil is configured to detect magnetic fields along one of the three axes and the three axes are orthogonal to each other. For example, the magnetometer is a RM3100 sensor commercially available from Positioning Navigation Intelligence although other types of magnetometers fall within the scope of this disclosure.

The set of Helmholtz coils 13 is arranged adjacent to the magnetometer and configured to generate magnetic fields for calibration, such that each Helmholtz coil is arranged in parallel with one of the three axes. The current source 14 is electrically coupled to the set of Helmholt coils 13. The current source energizes the set of Helmholt coils 13 with a signal that varies over time (e.g., an AC current). Preferably, each coil in the set of Helmholtz coils is energized with a signal having a different frequency from the other two coils in the set of Helmholtz coils.

During operation, the controller 15 is interfaced with the magnetometer 12 to receive the magnetic fields detected by the three sense coils and determines a calibration for the magnetometer by comparing the magnetic fields detected by the three sense coils to an expected magnetic field as will be explained in detail below. In an exemplary embodiment, the controller 15 is implemented as a microcontroller. It should be understood that the logic for the controller 15 can be implemented in hardware logic, software logic, or a combination of hardware and software logic. In this regard, controller 15 can be or can include any of a digital signal processor (DSP), microprocessor, microcontroller, or other programmable device which are programmed with software implementing the above described methods. It should be understood that alternatively the controller is or includes other logic devices, such as a Field Programmable Gate Array (FPGA), a complex programmable logic device (CPLD), or application specific integrated circuit (ASIC). When it is stated that controller 15 performs a function or is configured to perform a function, it should be understood that controller 15 is configured to do so with appropriate logic (such as in software, logic devices, or a combination thereof).

In most practical applications, the different contributions of specific error sources is not important, with the primary focus being the overall error contributions to a sensor. Therefore, most calibration algorithms simplify their sensor error model to a concise form:

$$\tilde{B} = T \times B + b + ∈$$

where \tilde{B} is the 3×n vector of the measurements of the magnetometer 12, B is the 3×n vector of the magnetic environment, and ∈ is the intrinsic Gaussian zero-mean measurement noise of the magnetometer 12.

Different studies make varying assumptions about the 3×3 error matrix, T, and 3×1 error bias/offset vector, b. However, error parameters and measured fields drift with time, and in-flight calibration is designed to measure how ground-calibrated error parameters drift with time.

The self-calibrating magnetometer system 10 is designed to measure how the error parameters of the magnetometer 12 drift with time while in-orbit on a spacecraft. The self-calibrating magnetometer system 10 is designed to estimate how error matrix T drifts with time. The self-calibrating magnetometer system 10 will be used in combination with common maximum likelihood in-flight calibration algorithms to quantify b, the combined bias terms, including sensor offset and hard-iron effects in each sensor axis. Maximum likelihood algorithms work by estimating the sensor axes' bias and iterating over that estimation for accuracy.

The self-calibrating magnetometer 10 estimates matrix T by generating sinusoidal magnetic field signals (or other varying signals, such as triangle waves, sawtooth, or square waves) and comparing the measured sinusoid amplitudes to the expected, generated sinusoid amplitudes.

Magnetic field sinusoids are generated using the Helmholtz coils 13 surrounding the magnetometer system 10, inputting precise modulating currents.

The current source 14 will generate the current, with a current regulator limiting the current to the amplitude of the magnetic field signals generated. The current source 14 may be the spacecraft's already existing electric power system. While reference is made in this disclosure to sinusoidal signals, other types of time varying signals may also be used to energize the Helmholtz coils.

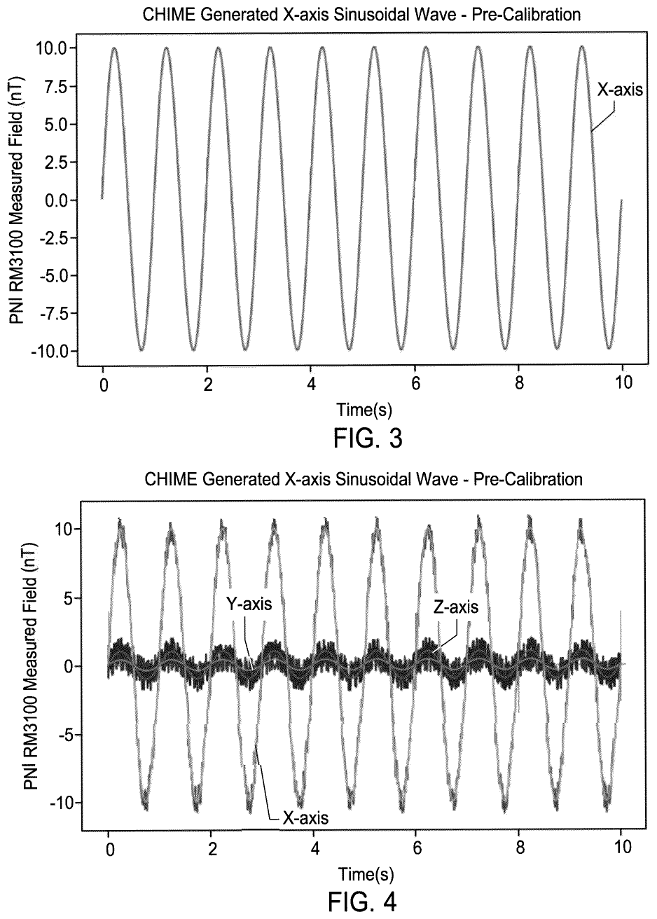

In a preferred embodiment, each of the Helmholtz coils 13 axis has a different signal frequency, so if all three axes are run at once, each sensor axis' scale factor and non-orthogonality terms may be separated. Generating magnetic signals on all three axes simultaneously is optimal for shortening the calibration interval and is viable because the magnetometer 12 has constant gains above 1 Hz. If the Helmholtz coils 13 dimensions and input current is known (and hence applied magnetic field amplitudes in each axis), the matrix T can be estimated. FIG. 3 is a graph of a single axis (x-axis) sinusoid magnetic field generated by the self-calibrating magnetometer system 10. Specifically, FIG. 3 depicts what the magnetometer 12, would measure if the magnetometer 12 measured perfectly. The magnetometer 12 has intrinsic noise in its measurement, scaling error that impacts the amplitude of the sine wave, and a perpendicularity error that causes the 3 sensor axes of the magnetometer 12 which should be completely perpendicular to bleed into each other.

FIG. 4 is a graph of the single axis (x-axis) sinusoid magnetic field as measured by the magnetometer 12. To eventually estimate error matrix T, the amplitudes of the measured sine waves are recorded as a vector:

$$[ \begin{matrix}10 \\ 0.4 \\ 1\end{matrix} ]$$

Amplitudes can be measured either through curve-fitting, Fourier analysis, or other analysis processes. Further, this process is done for the other two sensor axes of the magnetometer 12 (the y-axis and the z-axis). The vectors for each axis are combined to create an error matrix. For illustration purposes, an example error matrix follows:

$$[ \begin{matrix}10 & 2 & 0.6 \\ 0.4 & 9 & 1 \\ 1 & 0.5 & 10\end{matrix} ]$$

The process of obtaining the amplitudes of the sinusoids can be done simultaneously if the sine waves for each axis are generated with distinct frequencies because the functions can be separated.

Next, a calibration matrix is created such that the calibration matrix rotates and scales the error matrix to match an identification matrix, where the identification matrix:

$$[ \begin{matrix}1 & 0 & 0 \\ 0 & 1 & 0 \\ 0 & 0 & 1\end{matrix} ]$$

where each axis has a 1:1 magnetic field generation to measurement ratio and each axis is perpendicular (no measurements in one axis bleed into the other two). The calibration matrix would be the error matrix multiplied by the transposed normalization matrix multiplied by the pseudoinverse of the normalization matrix multiplied by the transposed normalization matrix.:

$$T = [ \begin{matrix}10 & 2 & 0.6 \\ 0.4 & 9 & 1 \\ 1 & 0.5 & 10\end{matrix} ] * {[ \begin{matrix}1 & 0 & 0 \\ 0 & 1 & 0 \\ 0 & 0 & 1\end{matrix} ]}^{T} * {( [ \begin{matrix}1 & 0 & 0 \\ 0 & 1 & 0 \\ 0 & 0 & 1\end{matrix} ] * {[ \begin{matrix}1 & 0 & 0 \\ 0 & 1 & 0 \\ 0 & 0 & 1\end{matrix} ]}^{T} )}^{†}$$

Therefore, the error matrix (values measured by the magnetometer 12) multiplied by the inverse of the calibration matrix equals the identification matrix:

$${T}^{- 1} = [ \begin{matrix}0.10127642 & - 0.02229213 & - 0.00384737 \\ - 0.00339474 & 0.11247907 & - 0.0110442 \\ - 0.00995791 & - 0.00339474 & 0.1193695\end{matrix} ]$$

$$[ \begin{matrix}10 & 2 & 0.6 \\ 0.4 & 9 & 1 \\ 1 & 0.5 & 10\end{matrix} ] \times [ \begin{matrix}0.10127642 & - 0.02229213 & - 0.00384737 \\ - 0.00339474 & 0.11247907 & - 0.0110442 \\ - 0.00995791 & - 0.00339474 & 0.1193695\end{matrix} ] = [ \begin{matrix}1 & 0 & 0 \\ 0 & 1 & 0 \\ 0 & 0 & 1\end{matrix} ]$$

To measure the correct matrix fields, B, from the magnetometer 12, the following equations are applied to the measurements from the magnetometer:

$${B}_{x} = 0.10127642 \times {S}_{1} - 0.02229213 \times {S}_{2} - 0.00384737 \times {S}_{3}$$

$${B}_{y} = - 0.00339474 \times {S}_{1} + 0.11247907 \times {S}_{2} - 0.0110442 \times {S}_{3}$$

$${B}_{z} = - 0.00995791 \times {S}_{1} - 0.00339474 \times {S}_{2} + 0.1193695 \times {S}_{3}$$

where S₁, S₂, and S₃ represent the 3-axis sensor of the magnetometer 12. This is an example of calibration values. In the example embodiment, the controller 15 implements the calibration process described above.

With this magnetometer error model, the magnetometer system 10 assumes it is perfectly aligned with the reference axis, the spacecraft body axis in this example (not depicted). This leads to the estimation of a T matrix with rotation error only from the internal sensor. However, when paired with an additional sensor, such as an inertial sensor, the self-calibrating magnetometer system 10 can quantify any change in coordinates between the two axes. The magnetometer system 10 uses a batch calibration method to estimate matrix, T, meaning it uses an entire set of measurements to estimate the unknown calibration parameters in matrix T. The calibration procedure is designed to be routinely repeated to calibrate soft-iron, time-varying scale factors with the assumption the error is divided into a combination of scale factor and non-orthogonality errors.

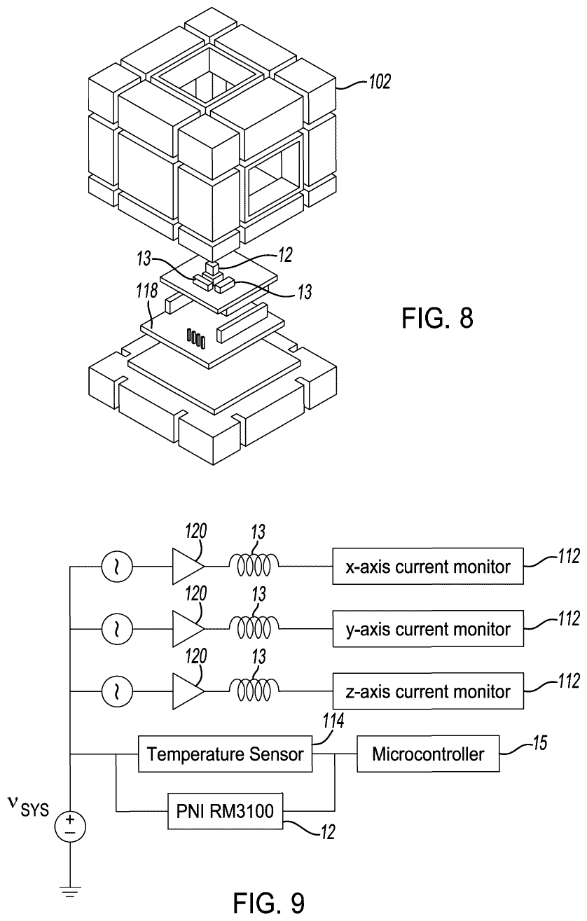

The self-calibrated magnetometer system 10 is designed to generate known magnetic fields to matrix T over time. It does so using the magnetometer 12 surrounded on 3-axes by the Helmholtz coils 13, which generate the calibration baseline magnetic fields. In one embodiment, magnetometer 12 and the Helmholtz coils reside in a housing 102 as seen in FIG. 8. With reference to FIG. 9, the magnetometer 104 maintains accuracy through a series of current regulators 120 and a temperature sensor 114, that identify deviations in programmed current values and sensor biases with temperature as further explained below.

The self-calibrating magnetometer system 10 measures the magnetic field using the magnetometer 12, which operates on the magneto-inductive principle. In the example embodiment, the magnetometer is a RM3100 magnetometer commercially available from Positioning Navigation Intelligence. The magnetometer 12 functions as a simple resistor-inductor circuit, avoiding the use of an analog-to-digital (A/D) converter which in traditional fluxgate magnetometers is sensitive to external radiation. The lack of an A/D converter and the absence of amplifiers, commonly found in fluxgate magnetometers, results in reduced power consumption, mass, and size. The RM3100 capitalizes on these advantages, consuming less than 10 mW of power, weighing just 3 g, and measuring 25 mm in width.

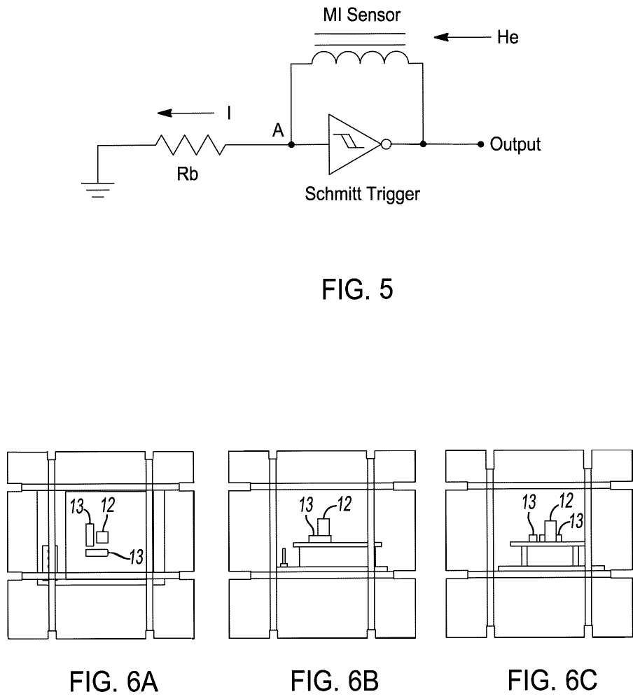

During flight, the controller 15 and associated electronics supply precise currents to the Helmholtz coils 13 for calibration. A commercial off-the-shelf version of the RM3100 magnetometer consists of orthogonal coils for the x-axis, y-axis, and z-axis respectively and an ASIC controller with peripheral electronics. The sensor operates by measuring the time required to charge and discharge an inductor between two thresholds using a relaxation oscillator. This time is proportional to the applied magnetic field strength within a specified range. In the commercial sensor, a register called “cycle count” controls the number of oscillator cycles used for integration, with its value inversely proportional to the sampling frequency. The electronics behind this process are illustrated in FIG. 5 which shows a resistor-inductor circuit, which measures magnetic fields by timing the charge/discharge of an inductor using a relaxation oscillator. The absence of an A/D converter and amplifiers reduces power consumption, mass and size.

The viability of the RM3100 magnetometer for space applications was demonstrated through a series of characterization and radiation tolerance experiments. The RM3100 magnetometer is radiation resistant across planetary environments and extremely tolerant to single event testing. It has a resolution of 2.7 nT and a noise floor of 4 pT at 1 Hz. This level of sensitivity is sufficient for high-quality scientific measurements.

Despite its many advantages, the RM3100 magnetometer is not an absolute magnetometer and has unknown drift in scale factor and offset over time. To correct for drift, the self-calibrating magnetometer system 10 measures scale factor and non-orthogonality by generating sinusoidal magnetic fields with known amplitudes using the Helmholtz coils 13, one pair for each of the three axis of the magnetometer 12. In the example embodiment, the Helmholtz coils 13 consist of two identical wire loops arranged parallel to each other, which produce a magnetic field when current is applied. The Helmholtz coils 13 create a three-axis homogeneous region of magnetic field to calibrate the magnetometer 12. FIGS. 6A-6C depict the arrangement of the magnetometer 12 in relation to the Helmholtz coils 13. The Helmholtz coils 13 are slightly offset from the geometric center of the magnetometer system 10 to account for the positional offset of the axes of the magnetometer 12.

To maximize the uniformity of the magnetic field while minimizing the coil volume, the optimal separation between the Helmholtz coils 13 is 0.5445 times the length of one coil side. In the example embodiment of magnetometer system 10, the Helmholtz coil pairs are stacked, with the z-axis coils being the smallest (49 mm side length) and separated by 13.4 mm. The y-axis coils measure 50 mm and are spaced 13.7 mm apart, while the x-axis coils are the largest (51 mm) with a separation of 13.9 mm. While reference is made in this disclosure to these dimensions, other dimensions following the same ratio may also be used. This example design ensures that the magnetic field within the magnetometer's axes varies by no more than 0.13%, confirmed through feedback field simulations. Each of the Helmholtz coils 13 is wound with 10 turns of 32 AWG copper wire, chosen to balance the strength of the generated magnetic field with wire durability. While reference is made in this disclosure to 32 AWG wire wound 10 turns, other wire sizes and turn amounts may also be used. While thinner wire can produce stronger fields, it is more fragile, and therefore makes the Helmholtz coils 13 more difficult to manufacture. The coils are held in place by a thermally stable ULTEM cube structure, maintaining coil volume in each axis and preventing overlap between loops. While reference is made in this disclosure to ULTEM material, other types of low thermal expansion materials may also be used.

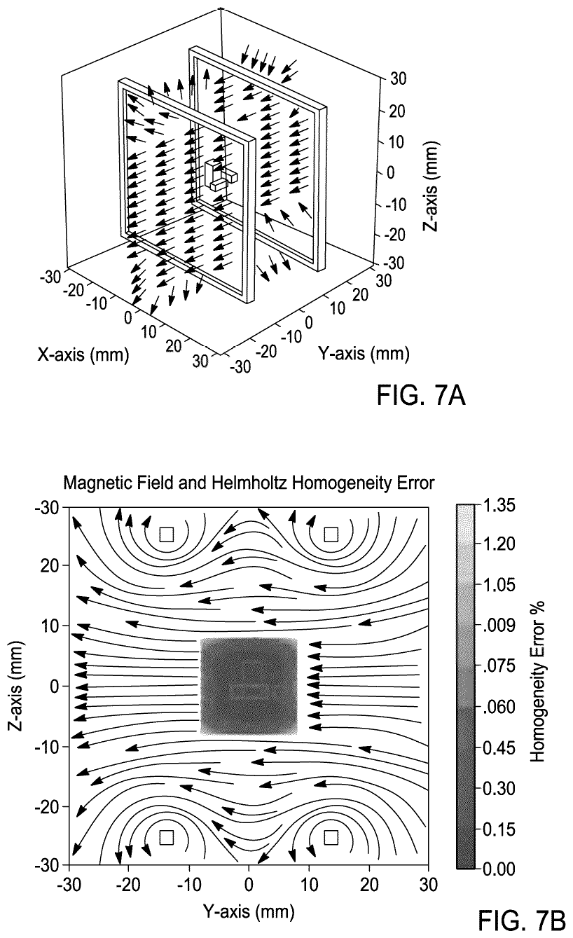

To analyze and optimize the design of the Helmholtz coil windings, a Biot-Savart simulation of the magnetic field generated by each axis' windings when a direct current is applied is developed. In this simulation, each loop of wire in the Helmholtz coil 13 is modeled as a square array with an assigned length and location on a 3D grid, rendered in FIG. 7A. For each axis, the resulting field values are summed and then normalized to create a model of the magnetic field homogeneity across the Helmholtz coil 13. Although the magnetometer system 10 calibrates its magnetometer 12 using sinusoidal AC (alternating current) magnetic fields, the Biot-Savart law, typically used for DC fields, remains accurate at low frequencies such as those used by the self-calibrating magnetometer system 10.

The simulation of the Helmholtz coil design suggests that the largest deviation from a uniform magnetic field along the 1D axis does not exceed 0.13%. The simulation of the magnetic field generated by the y-axis of the Helmholtz coils 13, rendered in FIG. 7B, is a slice at the plane x=0. The main region of interest is the area occupied by the magnetometer 12 sensor axes. The figure of merit for the Helmholtz coil 13 configuration is the percentage that the magnetic field values along each axis deviate from the sensor's origin. A smaller coil would introduce larger field variations, while a larger coil would use volume. This Helmholtz coil 13 size was also optimized for University of Michigan magnetic shielding containers and the RM3100 breakout board dimensions (31.3×28×20.7 mm).

In the example embodiment, the housing 102 was designed for durability, volume efficiency, and manufacturability. The housing 102 is made from ULTEM, a 3D-printable material widely used in aerospace due to its durability and high thermal stability (5.58×10-5 m/m C), though other high thermal stability materials may be used. Low thermal expansion is critical for the magnetometer system 10, as even slight changes in the size of the Helmholtz coils 13 can introduce significant calibration errors. The cube structure for the magnetometer system 10 was chosen for its durability. The magnetometer system 10 is relatively lightweight compared to other manufacturable magnetic sensors. Its dimensions of 52×52×52 mm were selected to accommodate the Helmholtz coils 13, as well as being the largest volume able to fit in magnetic shield cans at the University of Michigan test facilities. While reference is made in this disclosure to particular dimensions, volume and shape, other configurations are contemplated as well.

FIG. 8 illustrates an example implementation of the self-calibrating magnetometer residing in a housing 102. The housing 102 is printed in two halves, holding a breakout board 118 that communicates with the magnetometer 12. Once all components are assembled, the Helmholtz coils 13 are wound into channels that have been machined symmetrically into the ULTEM base so that there is no asymmetry or overlap in the coil loops of the Helmholtz coils 13. The winding channels for the Helmholtz coils 13 are deliberately positioned slightly off the geometric center of the base of the magnetometer 12. This adjustment maximizes the homogeneous field region around each sensor axis of the magnetometer 12, which is itself slightly offset from the geometric center of the magnetometer 12. The controller 15 is then wired through one of the cube's windows and connected to the Helmholtz coil 13 wiring alongside other sensor circuitry and power systems.

Referring to FIG. 9, circuitry of the magnetometer system 10 is designed to accurately deliver continuous operation to the magnetometer 12 as well as signal generation to the Helmholtz coils 13. For accurate calibration, precise knowledge of current values in the Helmholtz coils 13 is essential to maintain an accurate calibration baseline to compare measurements against. The magnetometer system 10 includes a current regulator 120 and a current monitoring system (e.g., a current sensor) 112. The current regulator 120 provides low noise AC current and prevents overloading, while the current monitoring system 112 records the actual current applied, rather than relying on the programmed value. This measured current is used during calibration to ensure more accurate results and maintain sensor precision. Without regulators, the magnetometer 12 requires less than 10 mW of power, depending on the selected sampling frequency. With regulators, the current system generates AC calibration signals for the Helmholtz coils 13, consuming approximately 1 mW of power. From an engineering standpoint, generating AC is less complex and a more stable alternative to maintaining a constant DC signal within the magnetometer system 10.

Optimal calibration metrics of the self-calibrating magnetometer system 10 are quantified, balancing power requirements for accuracy. Using these quantified values, performance of the magnetometer system 10 during quiet time orbits is determined. Next, with an accuracy baseline defined, it is determined which orbital regions the magnetometer system 10 accurately calibrates, regardless of geomagnetic activity.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A self-calibrating magnetometer system, comprising:
a magnetometer having three sense coils arranged to detect magnetic fields along three axes, each sense coil is configured to detect magnetic fields along one of the three axes and the three axes are orthogonal to each other;
a set of Helmholtz coils arranged adjacent to the magnetometer and configured to generate magnetic fields for calibration, each Helmholtz coil is arranged in parallel with one of the three axes;
a current source electrically coupled to the set of Helmholt coils, where the current source energizes the set of Helmholt coils with a signal that varies over time; and
a controller interfaced with the magnetometer to receive the magnetic fields detected by the three sense coils and determines a calibration for the magnetometer by comparing the magnetic fields detected by the three sense coils to an expected magnetic field.

2. The self-calibrating magnetometer system of claim 1 wherein the current source energizes the set of Helmholtz coils with an alternating current.

3. The self-calibrating magnetometer system of claim 1 wherein the current source is configured to energize each coil in the set of Helmholtz coils with a signal having a different frequency from the other two coils in the set of Helmholtz coils.

4. The self-calibrating magnetometer system of claim 1 wherein the controller determines a calibration for the magnetometer by
constructing an error matrix using the magnetic fields detected by the three sense coils, where, for each of the three sense coils, the error matrix represents the magnitude of the magnetic field along each of the three axes;
representing the expected magnetic fields with a normalization matrix;
calculating a calibration matrix using the error matrix and the normalization matrix; and
correcting the magnetic fields detected by the magnetometer using the calibration matrix.

5. The self-calibrating magnetometer system of claim 4 wherein the calibration matrix is calculated by computing the error matrix multiplied by the transposed normalization matrix multiplied by the pseudoinverse of the normalization matrix multiplied by the transposed normalization matrix.

6. The self-calibrating magnetometer system of claim 1 further comprises a current sensor coupled to each Helmholtz coil in the set of Helmholtz coils and configured to measure current applied to the Helmholtz coil.

7. The self-calibrating magnetometer system of claim 6 wherein the controller regulates the current applied to the Helmholtz coils by the current source based on the desired magnetic field.

8. The self-calibrating magnetometer system of claim 1 further comprises a temperature sensor arranged proximate to the magnetometer and interfaced with the controller, wherein the controller records deviations in magnetic fields detected from the magnetometer in relation to a measured temperature from the temperature sensor.

9. The self-calibrating magnetometer system of claim 1 wherein the magnetometer, the set of Helmholtz coils, the current source and the controller reside in a housing.

10. A self-calibrating magnetometer system, comprising:
a magnetometer having three sense coils arranged to detect magnetic fields along three axes, each sense coil is configured to detect magnetic fields along one of the three axes and the three axes are orthogonal to each other;
a set of Helmholtz coils arranged adjacent to the magnetometer and configured to generate magnetic fields for calibration, each Helmholtz coil is arranged in parallel with one of the three axes;
a current source electrically coupled to the set of Helmholt coils, where the current source is configured to energize each coil in the set of Helmholtz coils with a signal that varies over time and has a different frequency from the other two coils in the set of Helmholtz coils; and
a controller interfaced with the magnetometer to receive the magnetic fields detected by the three sense coils and calibrates magnetic fields measured by the magnetometer in accordance with expected magnetic field values.

11. The self-calibrating magnetometer system of claim 10 wherein the controller determines a calibration for the magnetometer by
constructing an error matrix using the magnetic fields detected by the three sense coils, where, for each of the three sense coils, the error matrix represents the magnitude of the magnetic field along each of the three axes;
representing the expected magnetic fields with a normalization matrix;
calculating a calibration matrix using the error matrix and the normalization matrix; and
correcting the magnetic fields detected by the magnetometer using the calibration matrix.

12. The self-calibrating magnetometer system of claim 11 wherein the calibration matrix is calculated by computing the error matrix multiplied by the transposed normalization matrix multiplied by the pseudoinverse of the normalization matrix multiplied by the transposed normalization matrix.

13. The self-calibrating magnetometer system of claim 10 further comprises a current sensor coupled to each Helmholtz coil in the set of Helmholtz coils and configured to measure current applied to the Helmholtz coil.

14. The self-calibrating magnetometer system of claim 13 wherein the controller regulates the current applied to the Helmholtz coils by the current source based on the desired magnetic field.

15. The self-calibrating magnetometer system of claim 10 further comprises a temperature sensor arranged proximate to the magnetometer and interfaced with the controller, wherein the controller records deviations in magnetic fields detected from the magnetometer in relation to a measured temperature from the temperature sensor.
